(19) United States
(12) Patent Application Publication
(10) Pub. No.: US 2025/0311309 A1
(43) Pub. Date: Oct. 2, 2025

(54) FLASH MEMORY DEVICE AND METHOD FOR FORMING THE SAME

(71) Applicant: Winbond Electronics Corp., Taichung City (TW)

(72) Inventors: Ping-Lung YU, Hsinchu City (TW); Po-Chun SHAO, Hsinchu City (TW); Chu-Chun HSIEH, Taichung City (TW)

(21) Appl. No.: 18/768,400

(22) Filed: Jul. 10, 2024

(30) Foreign Application Priority Data
Mar. 27, 2024 (TW) 113111451

(51) Int. Cl. H01L 29/788; H01L 21/324; H01L 21/762; H01L 21/768; H01L 29/423; H01L 29/66

(52) U.S. Cl. CPC H10D 30/68; H01L 21/324; H01L 21/76224; H01L 21/76825; H10D 30/0411; H10D 30/6891

(57) ABSTRACT

A flash memory device a method for forming the same are provided. The method includes providing a substrate. The substrate has shallow trench isolation features formed therein. The method further includes forming isolation features on the corresponding shallow trench isolation features. The isolation features have a first type of stress. The method further includes performing a surface treatment process on surface portions of the isolation features, so that the first type of stress of the surface portions of the isolation features is converted into a second type of stress. The method further includes forming a tunneling dielectric layer on the substrate. The method further includes forming a floating gate layer on the tunneling dielectric layer. The floating gate layer is in contact with the surface portions of the isolation features.

### CROSS REFERENCE TO RELATED APPLICATIONS

This application claims priority of Taiwan Patent Application No. 113111451, filed on Mar. 27, 2024, the entirety of which is incorporated by reference herein.

### BACKGROUND OF THE INVENTION

### Field of the Invention

The present disclosure relates to a flash memory device and a method for forming a flash memory device, and in particular, it is related to an isolation feature of a flash memory device and a method for forming an isolation feature of a flash memory device.

### Description of the Related Art

Flash memory is a non-volatile memory with high capacity, high read/write speeds, low power consumption, and low cost. Since flash memory is non-volatile, data remains stored in a flash memory even after the flash memory has been powered off. Therefore, flash memory is used widely.

In a NOR flash memory, the scaling-down of memory cells creates a bottleneck because of the problems that occur when the gate length and the gate width are decreased. For example, cracks may form at the interface between a self-aligned floating gate and an adjacent isolation feature due to stress mismatch, leading to electrical and reliability issues. Therefore, a novel flash memory and a method for forming the same are desirable to solve the aforementioned problems.

### BRIEF SUMMARY OF THE INVENTION

An embodiment of the disclosure provides a method for forming a flash memory device. The method includes providing a substrate. The substrate has shallow trench isolation features. The method further includes forming isolation features corresponding to and on the shallow trench isolation features. The isolation features have a first type of stress. The method further includes performing a surface treatment process on surface portions of the isolation features to convert the first type of stress of the surface portions of the isolation features into a second type of stress. The method further includes forming a tunneling dielectric layer on the substrate. The method further includes forming a floating gate layer on the tunneling dielectric layer. The floating gate layer is in contact with the surface portions of the isolation features.

An embodiment of the disclosure provides a flash memory device, including a substrate, shallow trench isolation features, isolation features, a tunneling dielectric layer and a floating gates. The shallow trench isolation features are formed in the substrate. The isolation features are located on the corresponding shallow trench isolation features. Each of the isolation feature has a surface portion and a central portion. The central portion is covered by the surface portion. The central portion has a first type of stress, and the surface portion has a second type of stress. The tunneling dielectric layer is formed on the substrate that is not covered by the isolation features. The floating gates are formed on the tunneling dielectric layer and located between the isolation features. The floating gates are in contact with the surface portions of the isolation features.

### BRIEF DESCRIPTION OF THE DRAWINGS

The present invention can be more fully understood by reading the subsequent detailed description and examples with references made to the accompanying drawings, wherein:

FIGS. 1 to 11 are schematic cross-sectional views of intermediate stages of a method for forming a flash memory device in accordance with some embodiments of the disclosure;

FIGS. 12A, 12B, and 12C are schematic diagrams of an outer surface profile and internal lattice atoms of an isolation feature of FIGS. 1, 3, and 9 in accordance with some embodiments of the disclosure, showing the variations of the isolation feature in surface roughness and lattice stress in the isolation feature caused by implanted dopant atoms during a surface treatment process shown in FIG. 2; and

FIG. 13 is a partially enlarged schematic view of FIG. 9, showing that dopants in the surface portion of the isolation feature will diffuse into the floating gate layer during the formation of the floating gate layer.

### DETAILED DESCRIPTION OF THE INVENTION

The following description is made for the purpose of illustrating the general principles of the invention and should not be taken in a limiting sense. The scope of the invention is best determined by reference to the appended claims.

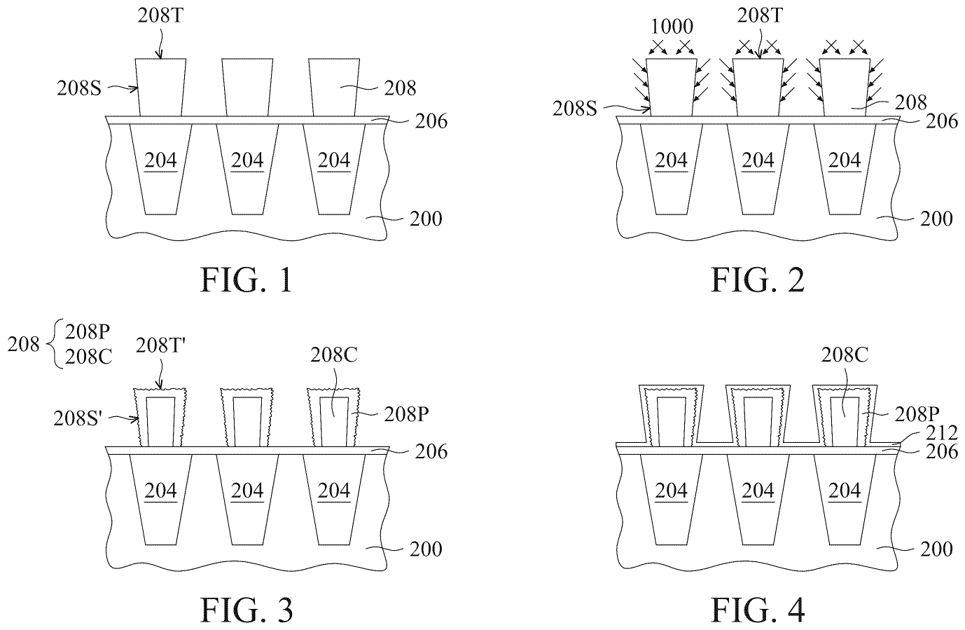

FIGS. 1 to 11 are schematic cross-sectional views of intermediate stages of a method for forming a flash memory device 500 in accordance with some embodiments of the disclosure. As shown in FIG. 1, a substrate 200 is provided. The semiconductor substrate 200 may be an elemental semiconductor substrate, such as a silicon substrate or a germanium substrate; or a compound semiconductor substrate, such as a silicon carbide substrate or a gallium arsenide substrate. In one embodiment, the semiconductor substrate 200 may be a silicon-on-insulator substrate. In this embodiment, the substrate 200 is a silicon substrate. The substrate 200 has shallow trench isolation features 204 formed therein. The shallow trench isolation features 204 may be formed of silicon oxide, silicon nitride, silicon oxynitride, or a combination thereof. In one embodiment, a patterning process is used to define the formation positions of the shallow trench isolation features 204. Next, a dielectric material for the shallow trench isolation features 204 is deposited using a deposition process. Next, the excess dielectric material on the surface of the substrate 200 is removed using a planarization process (chemical mechanical polishing, for example) to form the shallow trench isolation features 204. Next, a deposition process (such as thermal oxidation or chemical vapor deposition) may be performed to form an insulating pad layer 206 on the substrate 200. The insulating pad layer 206 is a pad oxide layer.

Next, a deposition process (such as high-density plasma chemical vapor deposition) and a subsequent patterning process may be performed to form corresponding isolation features 208 on the shallow trench isolation features 204. As shown in FIG. 1, the isolation feature 208 protrudes from the substrate 200 so that a top surface 208T of the isolation feature 208 and side surfaces 208S connected to the top surface 208T are located above the substrate 200. Furthermore, the isolation feature 208 is located directly above the corresponding shallow trench isolation feature 204. The isolation feature 208 may be formed of silicon oxide. In one embodiment, the isolation feature 208, such as silicon oxide deposited using high-density plasma chemical vapor deposition, has the type of stress of compressive stress.

Next, as shown in FIG. 2, a surface treatment process 1000 is performed on a surface portion 208P of the isolation feature 208 (i.e., the portion close to the top surface 208T and the side surfaces 208S of the isolation feature 208). The surface treatment process 1000 may include, for example, an ion implantation process to implant dopants in the surface portion 208P of the isolation feature 208. The dopants of the ion implantation process may include, for example, boron, carbon, silicon, germanium, nitrogen, phosphorus, arsenic, fluorine, argon or a combination thereof. In one embodiment, the implantation energy, dopant dose, and implantation angle range of the ion implantation process may be selected according to the geometric size and the spacing of the isolation feature 208, so as the dopants can be implanted on the entire surface portion 208P of the isolation feature 208. For example, the implantation energy of the ion implantation process may range from 1 keV to 100 keV. The dopant dose of the ion implantation process may range from 1E10 atoms/cm2 to 1E18 atoms/cm2. In addition, the implantation angle of the ion implantation process may range from 3 degrees to 30 degrees.

As shown in FIG. 3, after the surface treatment process 1000 is performed, the physical properties of the surface portion 208P of the isolation feature 208 will be changed (surface modification). For example, the top surface 208T and the side surfaces 208S of the isolation feature 208 will transform into the top surface 208T′ and the side surfaces 208S′ having greater roughness. Furthermore, the type of stress of the surface portion 208P of the isolation feature 208 may change from compressive stress to tensile stress or neutral stress. Alternatively, the value of compressive stress of the surface portion 208P of the isolation feature 208 after the surface treatment process 1000 may be lower than the value of the compressive stress of the surface portion 208P of the isolation feature 208 before the surface treatment process 1000. In one embodiment, the type of stress of the central portion 208C covered by the surface portion 208P maintains compressive stress after the surface treatment process 1000 is performed.

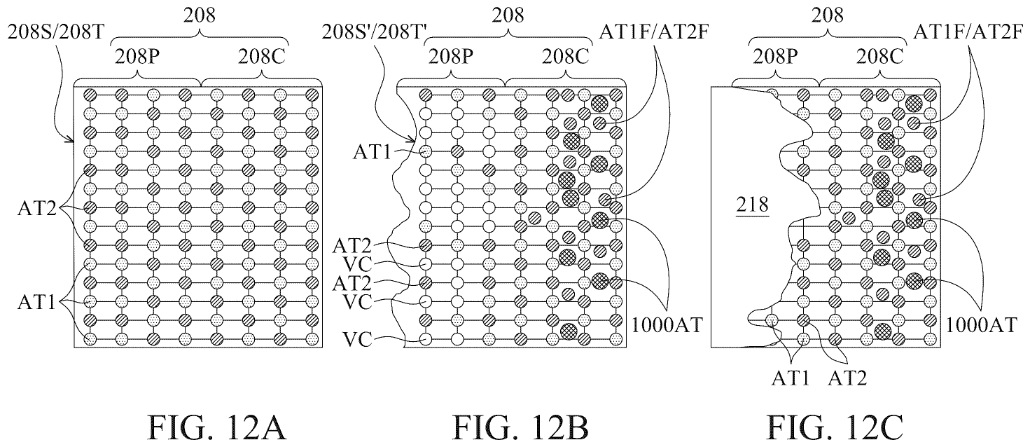

The impact on the isolation feature 208 due to the surface treatment process 1000 is further described with reference to FIGS. 12A and 12B. FIGS. 12A and 12B are schematic diagrams of the outer surface profile (for example, the surface profile of the side surface 208S or the top surface 208T) and the internal lattice atoms of the isolation feature 208 shown in FIGS. 1 and 3, showing the variations of the isolation feature 208 in surface roughness and lattice stress before and after performing the surface treatment process 1000. Please refer to FIGS. 1 and 12A, the lattice of the isolation feature 208 such as silicon oxide may be formed by a staggered arrangement of lattice atoms AT1 of oxygen atoms and lattice atoms AT2 of silicon atoms. Before performing the surface treatment process 1000, the outer surface of the isolation feature 208 (including the side surfaces 208S or the top surface 208T) is substantially a smooth surface. In addition, the surface portion 208P and the central portion 208C of the isolation feature 208 have the type of stress of compressive stress.

Please refer to FIGS. 2, 3, and 12B, when the surface treatment process 1000 such as an ion implantation process is performed on the isolation feature 208, the high-energy dopant (or dopant atoms) 1000AT will first bombard the side surfaces 208S or the top surface 208T of the isolation feature 208, which causes the surface roughness of the isolation feature 208 to increase. At the same time, the high-energy dopant (or dopant atoms) 1000AT may collide with a portions of the lattice atoms AT1 and AT2 of the surface portion 208P of the isolation feature 208 to transfer the energy from the high-energy dopant 1000AT to the collided lattice atoms AT1 and AT2. Therefore, the collided lattice atoms AT1 and AT2 gain energy and move away from their original lattice sites to become freed lattice atoms ATIF and AT2F, and lattice defects VC are generated at the original lattice sites. The free lattice atoms ATIF and AT2F then collide with the lattice atoms AT1 and AT2 at other lattice sites in the surface portion 208P to generate more freed lattice atoms ATIF and AT2F that enter the lattice gap of the central portion 208C of the isolation feature 208. Therefore, the outer surface of the isolation feature 208 is transformed into a rough surface (including the top surface 208T′ or the side surfaces 208S′) after performing the surface treatment process 1000. In other words, the top surface 208T′ and side surfaces 208S′ of the isolation feature 208 have a higher roughness than the top surface 208T and side surfaces 208S. Moreover, after the surface treatment process 1000 is performed, the type of stress of the surface portion 208P of the isolation feature 208 will change from compressive stress to tensile stress or neutral stress (or reduce the value of the compressive stress). In addition, the central portion 208C of the isolation feature 208 still maintains the original type of stress (i.e., compressive stress).

As shown in FIG. 4, after performing the surface treatment process 1000 (FIG. 2), a deposition process such as atomic layer deposition may be performed to form a capping layer 212 on the substrate 200 and the top surface 208T ‘and the side surfaces 208S’ of the isolation feature 208. The capping layer 212 may be used to protect the surface portion 208P of the isolation feature 208 from damage during the subsequent etching process of removing the insulating pad layer 206. In one embodiment, the insulating pad layer 206 and the capping layer 212 are formed of different materials. Furthermore, the isolation feature 208 and the capping layer 212 are formed of different materials. For example, the isolation feature 208 and the insulating pad layer 206 are formed of silicon oxide, and the capping layer 212 is formed of silicon nitride.

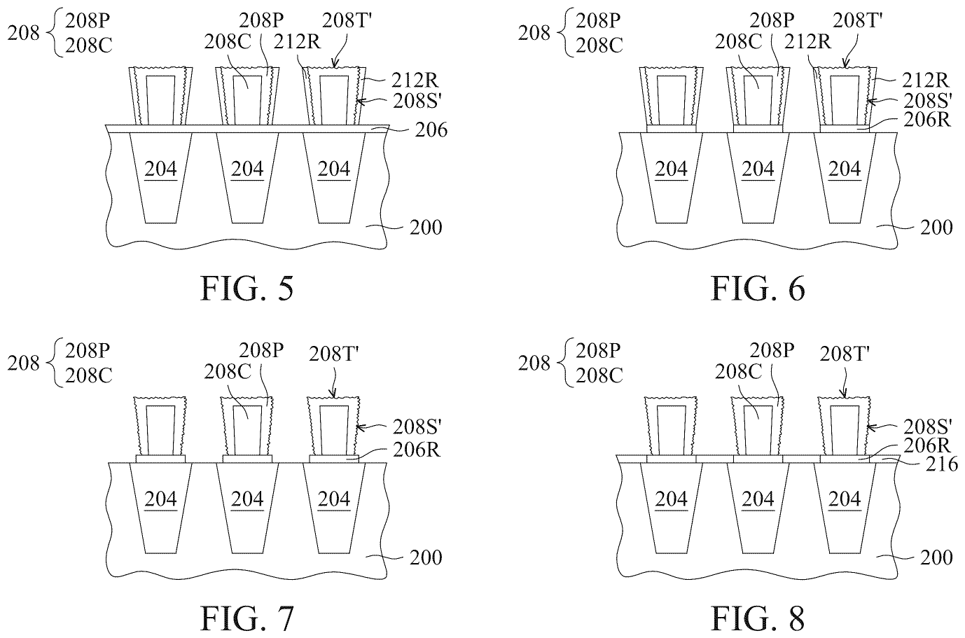

Next, as shown in FIG. 5, an etching process such as dry etching may be performed to remove the capping layer 212 on the substrate 200 and the top surface 208T′ of the isolation feature 208 to expose the top surface 208T′ of the isolation feature 208 and the insulating pad layer 206 not covered by the isolation feature 208. The remaining capping layer on the side surface 208S′ of the isolation feature 208 is denoted as a capping layer 212R.

Next, as shown in FIG. 6, an etching process such as dry etching or wet etching may be performed to remove the insulating pad layer 206 not covered by the isolation feature 208 to expose the substrate 200. The remaining insulating pad layer covered by the isolation feature 208 is denoted insulating pad layer 206R.

Next, as shown in FIG. 7, an etching process such as wet etching may be performed to selectively remove the capping layer 212R on the side surface 208S′ of the isolation feature 208 to expose the side surface 208S′ of the isolation feature 208. Since the capping layer 212R, such as silicon nitride, has a high etch selectivity relative to the isolation feature 208, such as silicon oxide, the removal of the capping layer 212R will not cause damage to the top surface 208T′ and the side surfaces 208S′ of the isolation feature 208.

Next, as shown in FIG. 8, a tunneling dielectric layer 216 is formed on the substrate 200 that is not covered by the isolation feature 208. The tunneling dielectric layer 216 may be adjacent to the insulating pad layer 206R. The tunneling dielectric layer 216 and the insulating pad layer 206R both may be formed of the same or similar material, such as silicon oxide. In one embodiment, the tunneling dielectric layer 216 may be formed by thermal oxidation or chemical vapor deposition.

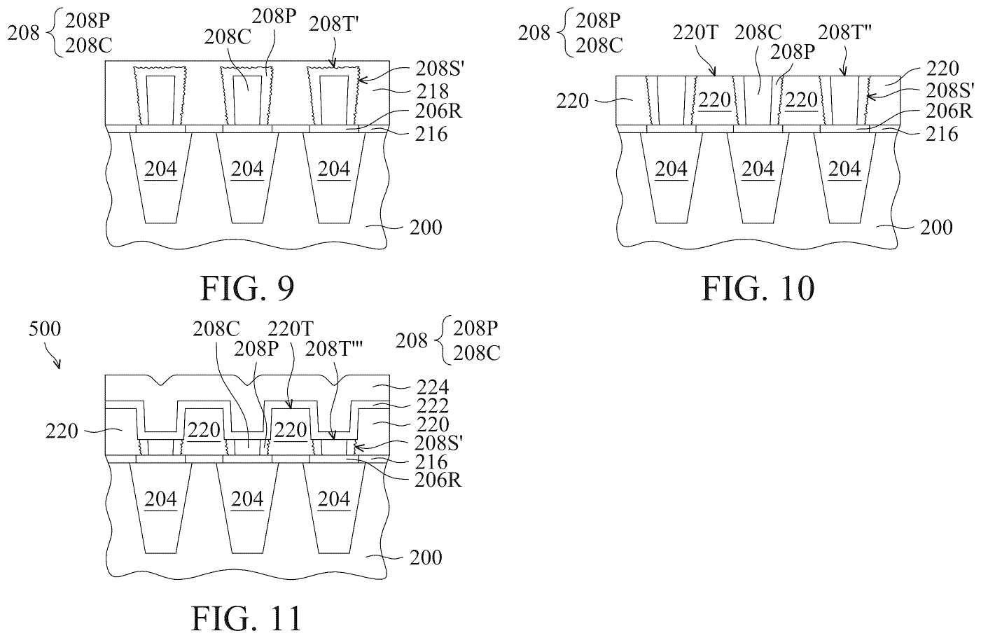

Next, as shown in FIG. 9, a deposition process may be performed to form a floating gate layer 218 such as amorphous silicon or polysilicon on the tunneling dielectric layer 216. An annealing process such as rapid thermal annealing may be performed subsequently to convert amorphous silicon into polysilicon. The temperature of the annealing process may range from 850° C. to 950° C., for example, about 900° C. In one embodiment, the floating gate layer 218 is in contact with the surface portion 208P of the isolation feature 208 (the floating gate layer 218 is in contact with the top surface 208T′ and the side surfaces 208S′ of isolation feature 208). FIG. 12C further illustrates the interface state between the floating gate layer 218 and the isolation feature 208 subjected to surface modification. As shown in FIG. 12C, since the surface treatment process 1000 (FIG. 2) may increase the surface roughness of the isolation feature 208, the adhesion between the floating gate layer 218 and the isolation feature 208 can be increased while the floating gate layer 218 is in contact with the rougher top surface 208T′ and side surfaces 208S′ of the isolation feature 208. Accordingly, cracks formed at the interface (i.e. the top surface 208T′ and the side surfaces 208S′) between the floating gate layer 218 and the isolation feature 208 due to the stress mismatch between them can be avoided.

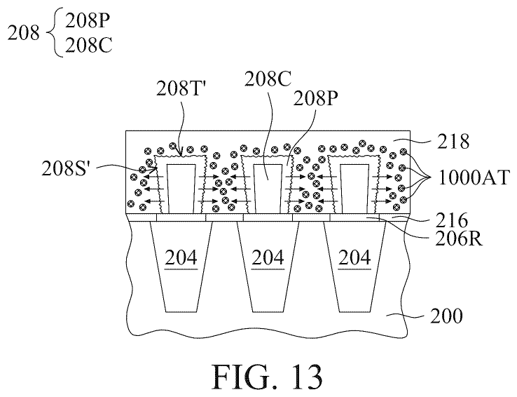

FIG. 13 is a partially enlarged schematic view of FIG. 9, showing that dopants 1000AT in the surface portion 208P of the isolation feature 208 will diffuse into the floating gate layer 218 during the annealing process to form the floating gate layer 218. In particular, the dopant 1000AT diffused into the floating gate layer 218 during the annealing process may also inhibit the grain growth of the floating gate layer 218, such as polysilicon, to avoid cracks formed at the interface between floating gate layer 218 and isolation features 208 resulting from the stress variation in the floating gate layer 218 due to the high-temperature annealing process and affecting the electrical properties and reliability of the resulting flash memory device.

Next, as shown in FIG. 10, a planarization process such as chemical mechanical polishing may be performed to remove a portion of the floating gate layer 218 and the modified portion of the top surface 208T′ of the isolation feature 208 until the central portion 208C of the isolation feature 208 is exposed, thereby forming floating gates 220 between the isolation features 208. As shown in FIG. 10, the top surface 220T of the floating gate 220 may be coplanar with a top surface 208T″ of the isolation feature 208 after performing the planarization process. In addition, the roughness of the top surface 208T″ of the isolation feature 208 may be less than the roughness of the side surface 208S′ of isolation feature 208. In this embodiment, the floating gate 220 is formed in a self-aligned manner and in contact with the side surface 208S′ of the isolation feature 208.

Next, as shown in FIG. 11, the isolation feature 208 may be selectively etched by wet etching, such as immersing in hydrofluoric acid (HF), so that the floating gate 220 protrudes from the isolation feature 208. More specifically, a top surface 208T′″ of the isolation feature 208 after selective etching is lower than the top surface 220T of the floating gate 220, and a portion of the side surface of the floating gate 220 is located above the top surface 208T′″ of the isolation feature 208′. Next, a deposition process such as chemical vapor deposition or atomic layer deposition may be performed to conformally form a gate dielectric layer 222 on the selectively etched isolation feature 208 and the top surface 220T and a portion of the side surfaces of the floating gate 220. The gate dielectric layer 222 may be in contact with the top surface 208T″ of the isolation feature 208. The gate dielectric layer 222 includes silicon oxide, silicon nitride, silicon oxynitride, or a triple-layer structure including silicon oxide/silicon nitride/silicon oxide (ONO). Since there are no cracks at the interface between the floating gate 220 and the isolation feature 208 subjected to surface modification, the etching solution used to selectively etch the isolation feature 208 will not etch the tunneling dielectric layer below the floating gate 220, thereby preventing the subsequently formed gate dielectric layer 222 from being in contact with the substrate 200. The electrical properties and reliability of the final flash memory device can be improved.

Next, referring to FIG. 11, a deposition process such as chemical vapor deposition may be performed to form a control gate layer 224 on the gate dielectric layer 222. After performing the aforementioned processes, the flash memory device 500 is formed. In one embodiment, the control gate layer 224 includes a layer of polysilicon or other conductive materials.

As shown in FIG. 11, the flash memory device 500 includes a substrate 200, shallow trench isolation features 204, isolation features 208, a tunneling dielectric layer 216, a floating gates 220, a gate dielectric electrical layer 222 and a control gate layer 224. The shallow trench isolation features 204 are formed in the substrate 200. The isolation features 208 are located on the corresponding shallow trench isolation features 204. The isolation feature 208 has a surface portion 208P and a central portion 208C covered by the surface portion 208P. In one embodiment, the central portion 208C of the isolation feature 208 has a first type of stress and the surface portion 208P has a second type of stress that is different from the first type of stress. The isolation feature 208 has a top surface 208T″ and side surfaces 208S′ connected to the top surface 208T″. In one embodiment, the top surface 208T″ of the isolation feature 208 has a first roughness and the side surface 208S′ has a second roughness. The second roughness is greater than the first roughness. The surface portion 208P of the isolation feature 208 may have a dopant including boron, carbon, silicon, germanium, nitrogen, phosphorus, arsenic, fluorine, argon, or a combination thereof. The tunneling dielectric layer 216 is formed on substrate 200 that is not covered by the isolation features 208. The floating gate 220 is formed on the tunneling dielectric layer 216 between the isolation features 208. The floating gate 220 is in contact with the surface portions 208P of isolation features 208. For example, the floating gate 220 is in contact with the side surfaces 208S′ of the isolation features 208. The floating gate 220 may have a dopant including carbon, nitrogen, argon, or a combination thereof. The gate dielectric layer 222 of the flash memory device 500 is formed on the isolation features 208 and the floating gate 220. The control gate layer 224 is formed on the gate dielectric layer 222.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method for forming a flash memory device, comprising:
providing a substrate, wherein the substrate has shallow trench isolation features formed therein;
forming isolation features on the corresponding shallow trench isolation features, wherein the isolation features have a first type of stress;
performing a surface treatment process on surface portions of the isolation features to convert the first type of stress of the surface portions of the isolation features into a second type of stress;
forming a tunneling dielectric layer on the substrate; and
forming a floating gate layer on the tunneling dielectric layer, wherein the floating gate layer is in contact with the surface portions of the isolation feature.

2. The method for forming a flash memory device as claimed in claim 1, wherein the surface portions of the isolation features have a first roughness before performing the surface treatment process, and wherein the surface portions of the isolation features have a second roughness after performing the surface treatment process, wherein the second roughness is greater than the first roughness.

3. The method for forming a flash memory device as claimed in claim 1, wherein the surface treatment process comprises an ion implantation process.

4. The method for forming a flash memory device as claimed in claim 3, wherein the ion implantation process implants a dopant in the surface portions of the isolation features.

5. The method for forming a flash memory device as claimed in claim 4, wherein the dopant comprises boron, carbon, silicon, germanium, nitrogen, phosphorus, arsenic, fluorine, argon or a combination thereof.

6. The method for forming a flash memory device as claimed in claim 4, further comprising:
performing an annealing process to diffuse the dopant in the surface portions of the isolation features into the floating gate layer after forming the floating gate layer.

7. The method for forming a flash memory device as claimed in claim 1, wherein the first type of stress is compressive stress, and wherein the second type of stress is tensile stress or neutral stress.

8. The method for forming a flash memory device as claimed in claim 1, wherein the first type of stress and the second type of stress are compressive stress, and a first stress value of the first type of stress is greater than a second stress value of the second type of stress.

9. The method for forming a flash memory device as claimed in claim 1, wherein each of the isolation features has a central portion covered by the surface portion, and the central portion has the first type of stress after performing the surface treatment process.

10. The method for forming a flash memory device as claimed in claim 1, further comprising:
forming an insulating pad layer on the substrate before forming the isolation features;
forming a capping layer on the substrate and the surface portions of the isolation features after performing the surface treatment process;
removing the capping layer on the substrate and top surfaces of the isolation features;
removing the insulating pad layer not covered by the isolation features to expose the substrate; and
removing the capping layer on sidewalls of the isolation features.

11. The method for forming a flash memory device as claimed in claim 1, further comprising:
performing a planarization process to remove a portion of the floating gate layer and the surface portions of top surfaces of the isolation features to form floating gates after forming the floating gate layer;
selectively etching the isolation features;
forming a gate dielectric layer on the selectively etched isolation features and the floating gates; and
forming a control gate layer on the gate dielectric layer.

12. The method for forming a flash memory device as claimed in claim 11, wherein the isolation features have side surfaces connected to the top surfaces, and after performing the planarization process, a roughness of the top surfaces of the isolation features is smaller than a roughness of the side surfaces.

13. A flash memory device, comprising:
a substrate;
shallow trench isolation features formed in the substrate;
isolation features located on the corresponding shallow trench isolation features, wherein each of the isolation features has a surface portion and a central portion covered by the surface portion, wherein the central portion has a first type of stress, and the surface portion has a second type of stress;
a tunneling dielectric layer formed on the substrate that is not covered by the isolation features; and
floating gates formed on the tunneling dielectric layer and located between the isolation features, wherein the floating gates are in contact with the surface portions of the isolation features.

14. The flash memory device as claimed in claim 13, wherein each of the isolation features has a top surface and side surfaces connected to the top surface, wherein the floating gates are in contact with the side surfaces of the isolation features, and wherein the top surface of each of the isolation features has a first roughness, and the side surfaces of each of the isolation features have a second roughness, and the second roughness is greater than the first roughness.

15. The flash memory device as claimed in claim 13, further comprising:
a gate dielectric layer formed on the isolation features and the floating gates; and
a control gate layer formed on the gate dielectric layer.

16. The flash memory device as claimed in claim 13, wherein the surface portions of the isolation features have a first dopant, the first dopant comprises boron, carbon, silicon, germanium, nitrogen, phosphorus, arsenic, fluorine, argon or a combination thereof.

17. The flash memory device as claimed in claim 13, wherein the floating gates have a second dopant, wherein the second dopant comprises carbon, nitrogen, argon or a combination thereof.
